(19) United States
(12) Patent Application Publication
(10) Pub. No.: US 2008/0191319 A1
(43) Pub. Date: Aug. 14, 2008

(54) SEMICONDUCTOR CHIP SUPPRESSING A VOID DURING A DIE ATTACHING PROCESS AND SEMICONDUCTOR PACKAGE INCLUDING THE SAME

(75) Inventor: Hyun-Jung WOO, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/966,761

(22) Filed: Dec. 28, 2007

(30) Foreign Application Priority Data
Jan. 3, 2007 (KR) 2007-0000681

(51) Int. Cl. H01L 23/58; H01L 23/52

(52) U.S. Cl. 257/622; 257/777; 257/E23.002; 257/E23.141

(57) ABSTRACT

Provided are a semiconductor chip and a semiconductor package including the semiconductor chip. The semiconductor chip includes a void suppressing path formed in an upper surface of the semiconductor chip and extending to a scribe line formed at an edge of the semiconductor chip.

### CROSS-REFERENCE TO RELATED PATENT APPLICATION

This application claims priority under 35 USC § 119 to Korean Patent Application No. 10-2007-0000681, filed on Jan. 3, 2007 in the Korean Intellectual Property Office, the contents of which are incorporated herein in their entirety by reference.

### BACKGROUND

1. Technical Field

The present invention relates to a semiconductor chip and a semiconductor package including the same, and more particularly, to a semiconductor chip used in a stack type semiconductor package and the stack type semiconductor package including the same.

2. Description of the Related Art

In order to achieve a high degree of integration of semiconductor devices functioning as memories, semiconductor wafers are manufactured to be very thin. Also, internal components of the semiconductor devices, such as transistors or capacitors, are 3-dimensionally arranged in order to manufacture more integrated circuits (ICs) within the wafers. A technique for vertically stacking thin semiconductor chips has recently been used to mount many semiconductor chips in a semiconductor package so as to increase the degree of integration of the semiconductor package.

Compared to a method of increasing integration during the manufacture of a wafer, a method of increasing integration of semiconductor memory devices through semiconductor package manufacturing technology instead of wafer manufacturing technology has many advantages in terms of cost, time required for research and development, and realization of processes. Thus, research has been increasingly directed to increasing the degree of integration of semiconductor devices by advancing semiconductor package manufacturing technology.

FIG. 1 is a cross-sectional view illustrating a method of manufacturing a conventional stack type semiconductor package. Referring to FIG. 1, a process of mounting semiconductor chips 20A and 20B on a substrate 10 using adhesives 22A and 22B, such as adhesive tapes, is generally performed during a die attaching process. The semiconductor chip 20B is picked up using vacuum to put the semiconductor chip 20B above the substrate 10 using a collet 40 during the die attaching process. Here, the collet 40 picks up the semiconductor chip 20B using vacuum, and thus a central portion of the semiconductor chip 20B is slightly warped when mounted above the substrate 10. Such a warping phenomenon becomes more serious when the semiconductor chips 20A and 20B are thin.

When the collet 40 picks up the semiconductor chip 20B to put the semiconductor chip 20B above the substrate 10 or on the semiconductor chip 20A, the semiconductor chip 20B must be substantially horizontal in order to ensure proper placement. However, in conventional processes, the semiconductor chip 20B may be mounted with a slant due to a problem in the die attaching equipment or other causes.

FIG. 2 is a cross-sectional view illustrating a stack type semiconductor package including semiconductor chips between which a void is formed, and FIG. 3 is a plan view of the stack type semiconductor package. Referring to FIGS. 2 and 3, a warpage or tilt of a semiconductor chip 20B is caused by a void 12 remaining in the semiconductor package after the semiconductor package is completely assembled. The void 12 is developed into a swelling defect or a delamination defect after a molding process for sealing the semiconductor package is completed. Also, if a process such as an oven cure process is performed, vapor in the void 12 is expanded. Thus, a crack is formed in the semiconductor package as the expanded vapor creates a path to escape the semiconductor package.

Semiconductor chips stacked in a stack type semiconductor package must be thinner in order to increase the number of semiconductor chips in the package. Thus, the above described problems must be solved in order to realize a highly reliable stack type semiconductor package.

### SUMMARY

The present invention provides a semiconductor chip having an improved structure to suppress a void occurring during a die attaching process and a semiconductor package including the semiconductor chip.

According to an aspect of the present invention, there is provided a semiconductor chip suppressing a void, including a semiconductor chip and; a void suppressing path formed in an upper surface of the semiconductor chip and extending to a scribe line formed at an edge of the semiconductor chip.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view illustrating a method of manufacturing a general stack type semiconductor package;

FIG. 2 is a cross-sectional view illustrating a stack type semiconductor package including semiconductor chips between which a void is formed;

FIG. 3 is a plan view of the stack type semiconductor package of FIG. 2;

FIG. 4 is a plan view of a semiconductor chip according to an embodiment of the present invention;

FIGS. 5 through 9 are plan views of modified semiconductor chips according to some embodiments of the present invention;

FIG. 10 is a cross-sectional view illustrating semiconductor chips stacked on a substrate according to an embodiment of the present invention;

FIG. 11 is a bottom view illustrating a semiconductor chip according to another embodiment of the present invention;

FIG. 12 is a cross-sectional view illustrating semiconductor chips stacked on a substrate according to another embodiment of the present invention;

FIG. 13 is a cross-sectional view of a semiconductor package including semiconductor chips according to an embodiment of the present invention; and

FIG. 14 is a cross-sectional view of a modified semiconductor package including semiconductor chips according to an embodiment of the present invention.

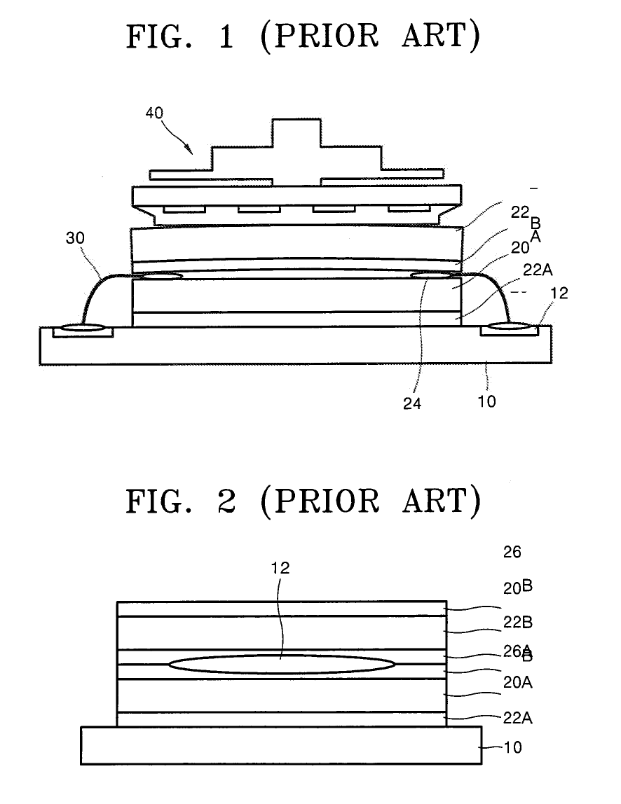

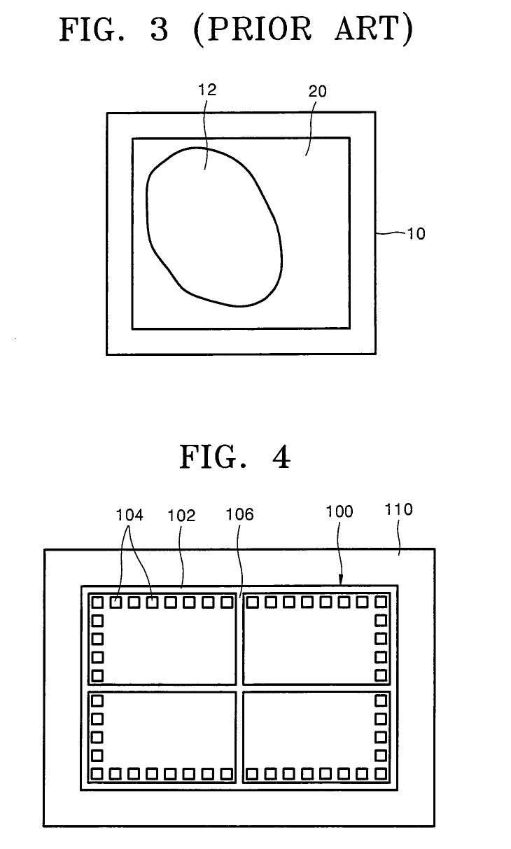

### DETAILED DESCRIPTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

FIG. 4 is a plan view of a semiconductor chip according to an embodiment of the present invention. Referring to FIG. 4, a semiconductor chip 100 is mounted on a substrate 110 including printed circuit patterns, and a scribe line 102 is formed at an edge of the semiconductor chip 100. The scribe line 102 denotes a line along which the semiconductor chip 100 is diced from a wafer.

A void suppressing path 106 is additionally formed on an upper surface of the semiconductor chip 100 to a predetermined depth so as to extend to the scribe line 102. A depth of the void suppressing path 106 may be within a range between about 3 μm and about 10 μm. Also, a plurality of bond pads 104 are formed near the edge of the semiconductor chip 100.

According to some embodiments of the present invention, although a void may be formed during a die attaching process, vapor in the void is discharged through the void suppressing path 106 outside of a semiconductor package. Thus, the void suppressing path 106 reduces the adverse effects of a void in the semiconductor package.

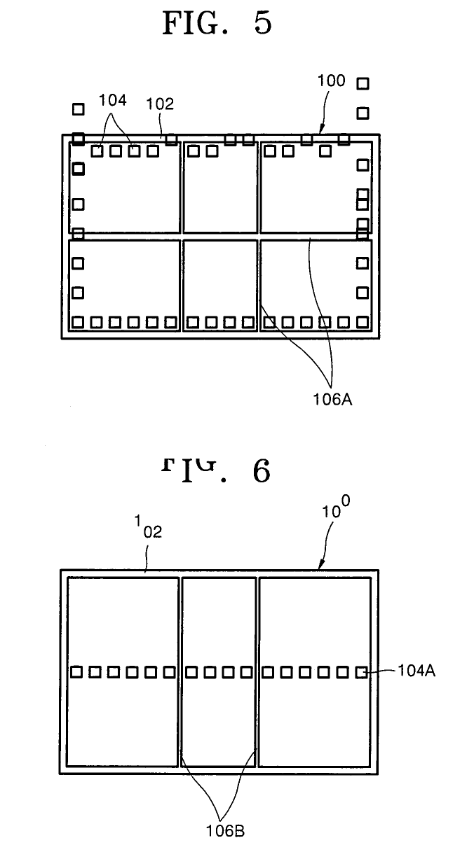

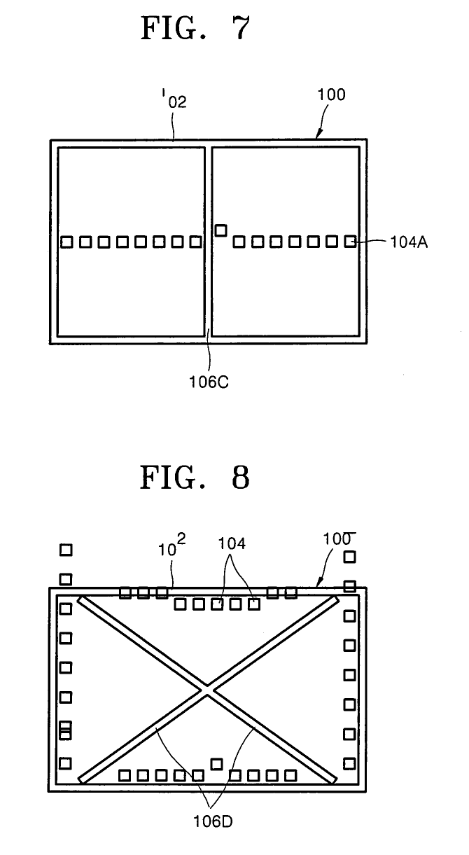

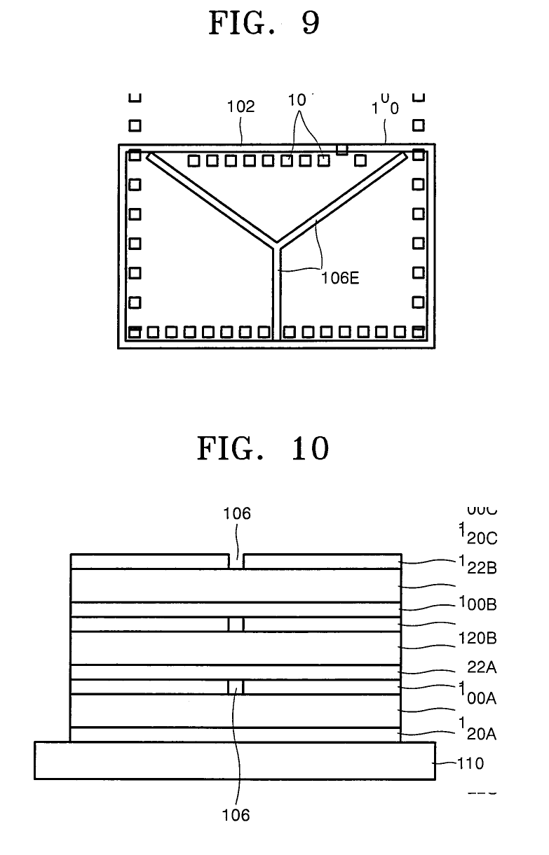

FIGS. 5 through 9 are plan views of modified semiconductor chips according to some embodiments of the present invention. The void suppressing path 106 of FIG. 4 has a cross shape. However, FIGS. 5 through 9 illustrate void suppressing paths 106A, 106B, 106C, 106D, and 106D having various shapes. Here, the void suppressing path 106A horizontally and vertically crosses the semiconductor chip 100, the void suppressing paths 106B and 106C vertically cross the semiconductor chip 100, and the void suppressing paths 106D and 106E obliquely cross the semiconductor chip 100. Also, different from the bond pads 104 of FIG. 4 formed at the edge of the semiconductor chip 100, bond pads 104A of FIGS. 6 and 7 may be formed near a center portion of the semiconductor chip 100.

FIG. 10 is a cross-sectional view illustrating semiconductor chips stacked on a substrate according to an embodiment of the present invention. Referring to FIG. 10, semiconductor chips 100A, 100B, and 100C are vertically stacked above a substrate 110 in which printed circuit patterns are formed. The semiconductor chips 100A, 100B, and 100C are stacked above the substrate 110 using adhesives, e.g., adhesive tapes 120A, 120B, and 120C, respectively. The adhesives may be liquid epoxy instead of adhesive tapes. Coating layers 122A, 122B, and 122C may be formed of polyimide or photosensitive polyimide on the semiconductor chips 100A, 100B, and 100C. The coating layers 122A, 122B, and 122C may be patterns which protect cell areas and fuse patterns of a semiconductor memory device and may be selectively formed. Void suppressing paths 106 are additionally formed in the coating layers 122A, 122B, and 122C, respectively. In a case of a semiconductor chip which does not need the coating layers 122A, 122B, and 122C, the void suppressing paths 106 may be formed of an upper surface of semiconductor chips 100A, 100B and 100C, e.g., a passivation layer.

When a thin semiconductor chip is picked up using a collet on a piece of die attaching equipment, the thin semiconductor chip may be warped. Thus, a void may be formed when the thin semiconductor chip is placed on a substrate or another semiconductor chip. However, according to embodiments of the present invention, vapor in the void may be discharged through the void suppressing paths 106. Therefore, the formation of large voids in the centers of the semiconductor chips 100A, 100B, and 100C is suppressed. As a result, process defects in a completed semiconductor package such as swelling, delamination, and cracks can be minimized.

In FIG. 10, three semiconductor chips are stacked. However, the number of semiconductor chips may be 2, 4, or more. Although not shown, the void suppressing paths 106 may be additionally formed in lower surfaces of the semiconductor chips 100A, 100B, and 100C as shown in FIG. 12.

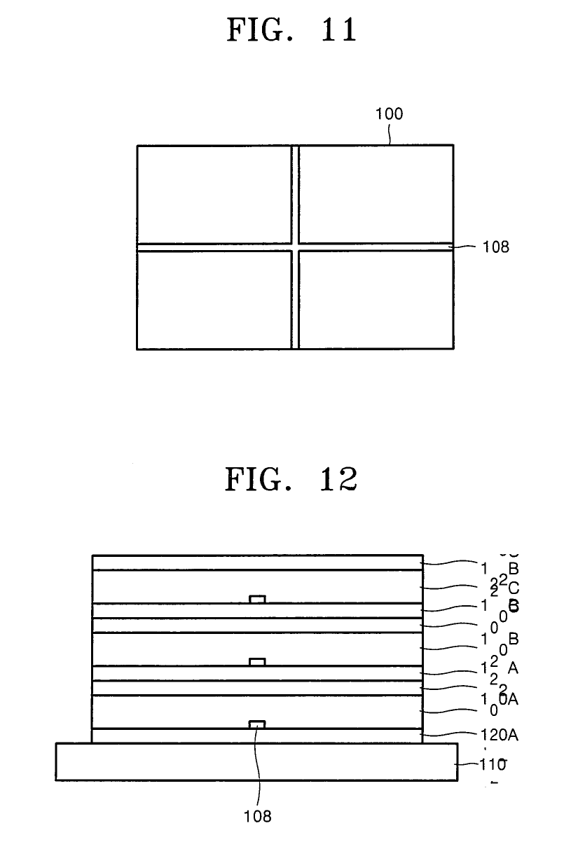

FIG. 11 is a bottom view illustrating a semiconductor chip suppressing a void according to another embodiment of the present invention.

The void suppressing path 106 of FIG. 4 is disposed on the upper surface of the semiconductor chip 100. However, a void suppressing path 108 of FIG. 11 is formed in a lower surface of a semiconductor chip 100. A valley having a width within a range between about 3 μm and about 10 μm is formed in the lower surface of the semiconductor chip 100 using a laser. The void suppressing path 108 may be formed in a cross shape. Alternatively, the void suppressing path 108 may be formed in various shapes as illustrated in FIGS. 5 through 9 so as to horizontally, vertically, or obliquely cross the semiconductor chip 100.

FIG. 12 is a cross-sectional view illustrating semiconductor chips stacked on a substrate according to another embodiment of the present invention. Referring to FIG. 12, semiconductor chips 100A, 100B, and 100C are vertically stacked on a substrate 110 in which printed circuit patterns are formed. Void suppressing paths 108 are formed in lower surfaces of the semiconductor chips 100A, 100B, and 100C. Adhesives 120A, 120B, and 120C, e.g., adhesive tapes or liquid epoxy, are formed underneath the semiconductor chips 100A, 100B, and 100C, respectively. Coating layers 122A, 122B, and 122C are selectively formed of polyimide or photosensitive polyimide on the semiconductor chips 100A, 100B, and 100C, respectively. Thus, vapor is discharged through the void suppressing paths 108 formed in the lower surfaces of the semiconductor chips 100A, 100B, and 100C outside of a semiconductor package so that a void formed in a die attaching process does not cause failure of the package.

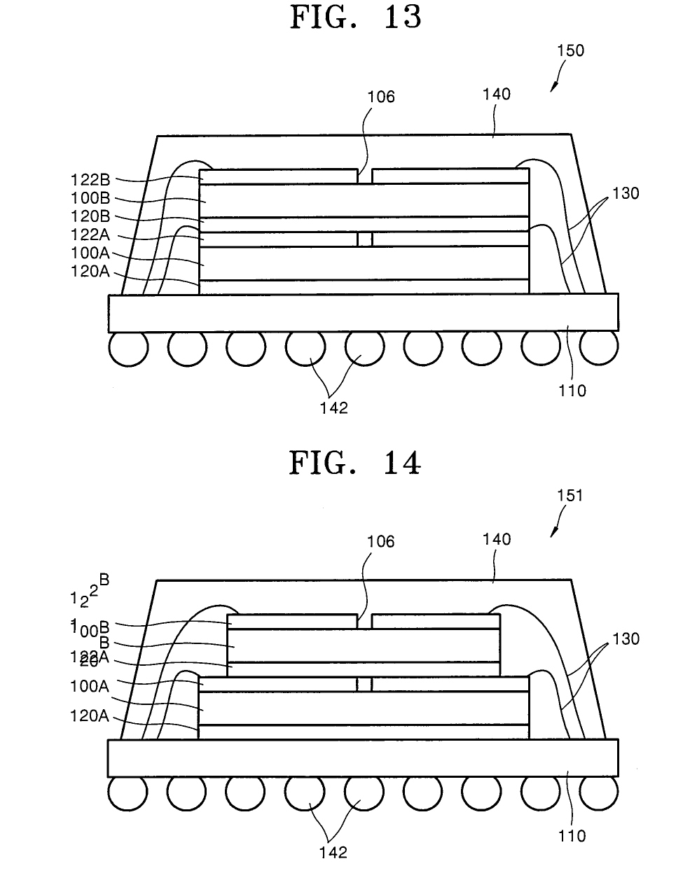

FIG. 13 is a cross-sectional view of a semiconductor package including semiconductor chips according to an embodiment of the present invention. Referring to FIG. 13, a semiconductor package 150 according to the present embodiment includes a substrate 110, a first semiconductor chip 100A, a second semiconductor chip 100B, connectors 130, a sealant 140, and external connection terminals, for example solder balls, 142. The substrate 110 includes printed circuit patterns. The first semiconductor chip 100A is mounted on the substrate 110 using an adhesive 120A, and a void suppressing path 106 is formed in an upper surface of the first semiconductor chip 100A to a predetermined depth. The semiconductor chip 100B is mounted on the first semiconductor chip 100A using an adhesive 120B, and a void suppressing path 106 is formed in an upper surface of the second semiconductor chip 100B to a predetermined depth. The connectors 130 electrically connect bond pads of the first and second semiconductor chips 100A and 100B to the printed circuit patterns of the substrate 110. The sealant 140 seals the first and second semiconductor chips 100A and 100B and the connectors 130 on the substrate 100. The external connection terminals 142 are attached underneath the substrate 110.

Here, the first and second semiconductor chips 100A and 100B have the same size, and the void suppressing paths 106 are formed in coating layers 122A and 122B respectively formed on the first and second semiconductor chips 100A and 100B. The connectors 130 are wires but may be other connecting parts connecting the first and second semiconductor chips 100A and 100B to the substrate 110, e.g., conductive bumps such as solder bumps. Also, the adhesives 120A and 120B may be liquid epoxy instead of adhesive tapes.

The semiconductor package 150 is illustrated as an example and thus may be modified into other forms using the void suppressing paths 106. Void suppressing paths 108 as illustrated in FIG. 11 may be additionally formed in lower surfaces of the first and second semiconductor chips 100A and 100B.

FIG. 14 is a cross-sectional view of a modified semiconductor package including semiconductor chips according to an embodiment of the present invention. The first and second semiconductor chips 100A and 100B of FIG. 13 have the same size. However, first and second semiconductor chips 100A and 100B of FIG. 14 may have different sizes. Other components of the semiconductor package of FIG. 14 are similar to those of FIG. 13, and thus their detailed descriptions have been omitted.

As described above, according to the present invention, a void suppressing path additionally formed in an upper or lower surface of a semiconductor chip can suppress a void. Thus, a swelling defect and a crack defect in a stack type semiconductor package can be prevented. As a result, a highly reliable stack type semiconductor package can be manufactured.

According to an aspect of the present invention, there is provided a device including: a semiconductor chip; and a void suppressing path disposed in an upper surface of the semiconductor chip and extending to a scribe line disposed at an edge of the semiconductor chip.

A depth of the void suppressing path may be within a range between about 3 μm and about 10 μm, and the void suppressing path may horizontally, vertically, or obliquely cross the semiconductor chip.

The void suppressing path may be disposed in a passivation layer disposed on an upper surface of the semiconductor chip, or in a coating layer disposed on the passivation layer.

The bond pads may be disposed at an edge of the semiconductor chip, at a center of the semiconductor chip, or in a lower surface of the semiconductor chip.

According to another aspect of the present invention, there is provided a device including: a semiconductor chip; and a void suppressing path disposed in a lower surface of the semiconductor chip to a predetermined depth and extending to a scribe line disposed at an edge of the semiconductor chip.

According to another aspect of the present invention, there is provided a semiconductor package including: a substrate including printed circuit patterns; a first semiconductor chip mounted on the substrate using a first adhesive and including a void suppressing path formed in a lower surface of the first semiconductor chip to a predetermined depth; a second semiconductor chip mounted on the first semiconductor chip using a second adhesive and including a void suppressing path formed in an upper surface of the second semiconductor chip to a predetermined depth; connectors connecting bond pads of the first and second semiconductor chips to the printed circuit patterns of the substrate; and a sealant sealing the first and second semiconductor chips on the substrate and the connectors.

A depth of each of the void suppressing paths of the first and second semiconductor chips may be within a range between about 3 μm and about 10 μm. Further, the first and second semiconductor chips may have substantially identical sizes or different sizes.

The adhesives may be adhesive tapes or liquid epoxy and the connectors may be wires or conductive bumps.

The first and second semiconductor chips may further include void suppressing paths formed in lower surfaces of the first and second semiconductor chips.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A device, comprising:
a semiconductor chip; and
a void suppressing path disposed in an upper surface of the semiconductor chip and extending to a scribe line disposed at an edge of the semiconductor chip.

2. The device of claim 1, wherein a depth of the void suppressing path is within a range between about 3 μm and about 10 μm.

3. The device of claim 1, wherein the void suppressing path horizontally, vertically, or obliquely crosses the semiconductor chip.

4. The device of claim 1, wherein the void suppressing path is disposed in a passivation layer disposed on an upper surface of the semiconductor chip.

5. The device of claim 1, wherein the void suppressing path is disposed in a coating layer disposed on a passivation layer of the semiconductor chip.

6. The device of claim 5, wherein the coating layer is one of a polyimide layer and a photosensitive polyimide layer.

7. The device of claim 1, wherein bond pads are disposed at an edge of the semiconductor chip.

8. The device of claim 1, wherein bond pads are disposed at a center of the semiconductor chip.

9. The device of claim 1, further comprising a void suppressing path disposed in a lower surface of the semiconductor chip.

10. A device, comprising:
a semiconductor chip; and
a void suppressing path disposed in a lower surface of the semiconductor chip to a predetermined depth and extending to a scribe line disposed at an edge of the semiconductor chip.

11. The device of claim 10, wherein a depth of the void suppressing path is within a range between about 3 μm and about 10 μm.

12. The semiconductor chip of claim 10, wherein the void suppressing path horizontally, vertically, or obliquely crosses the semiconductor chip.

13. A semiconductor package, comprising:
a substrate including printed circuit patterns;
a first semiconductor chip mounted on the substrate using a first adhesive and comprising a void suppressing path disposed in a lower surface of the first semiconductor chip to a predetermined depth;
a second semiconductor chip mounted on the first semiconductor chip using a second adhesive and comprising a void suppressing path disposed in an upper surface of the second semiconductor chip to a predetermined depth;
connectors connecting bond pads of the first and second semiconductor chips to the printed circuit patterns of the substrate; and
a sealant sealing the first and second semiconductor chips on the substrate and the connectors.

14. The semiconductor package of claim 13, wherein a depth of each of the void suppressing paths of the first and second semiconductor chips is within a range between about 3 μm and about 10 μm.

15. The semiconductor package of claim 13, wherein the first and second semiconductor chips have different sizes.

16. The semiconductor package of claim 13, wherein the first and second semiconductor chips have substantially identical sizes.

17. The semiconductor package of claim 13, wherein the first and second adhesives are adhesive tapes.

18. The semiconductor package of claim 13, wherein the first and second adhesives are liquid epoxy.

19. The semiconductor package of claim 18, wherein the first and second semiconductor chips further comprise void suppressing paths disposed in lower surfaces of the first and second semiconductor chips.

20. The semiconductor package of claim 13, wherein the connectors are wires or conductive bumps.
